(19) United States
(12) Patent Application Publication
(10) Pub. No.: US 2009/0057870 A1
(43) Pub. Date: Mar. 5, 2009

(54) STACKED SEMICONDUCTOR PACKAGE WITH A REDUCED VOLUME

(76) Inventor: Qwan Ho CHUNG, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 11/868,041

(22) Filed: Oct. 5, 2007

(30) Foreign Application Priority Data
Aug. 31, 2007 (KR) 10-2007-0088386

(51) Int. Cl. H01L 23/49

(52) U.S. Cl. 257/691; 257/E23.024

(57) ABSTRACT

The stacked semiconductor package includes a substrate having a plurality of connection pads; a first semiconductor chip disposed over the substrate, a plurality of first bonding pads disposed at an first of the first semiconductor chip, redistributions extending from the first bonding pads to the middle of the upper face; wires for electrically connecting the first bonding pads to the connection pads; and a second semiconductor chip disposed over the first semiconductor chip leaving the first bonding pads exposed, and a plurality of second bonding pads disposed over the second semiconductor chip body and connected to the redistributions in a flip-chip manner. The stacked semiconductor package with this structure has a decreased volume, thus making the stacked semiconductor package more compact.

### CROSS-REFERENCE TO RELATED APPLICATIONS

The present application claims priority to Korean patent application number 10-2007-0088386 filed on Aug. 31, 2007, which is incorporated herein by reference in its entirety.

### BACKGROUND OF THE INVENTION

The present invention relates to a stacked semiconductor package, and more particularly to a stacked package that is reduced in volume to allow for a more compact size.

Recent developments in semiconductor packages have led to a semiconductor package having a semiconductor device that is adapted to store massive amounts of data and process the stored data in short time.

Generally, a semiconductor package is fabricated both using a semiconductor chip fabrication process for fabricating a semiconductor chip by integrating devices such as a transistor, a resistor, a capacitance, etc. on a wafer, and a packaging process for singulating the semiconductor chip from the wafer, connecting electrically it to an external circuit board and protecting the semiconductor with weak brittleness from an external impact and/or vibration.

In particular, a wafer level package having a size no larger than 100% to 105% of the semiconductor chips size and a stacked semiconductor package with a plurality of stacked semiconductor chips has been recently developed.

The stacked semiconductor package has an advantage in that its data storage capacity and/or data processing ability are largely enhanced because it has a plurality of semiconductor chips.

However, the stacked semiconductor package has a problem. Its volume is greatly increased as the semiconductor chips are stacked. In order to solve this problem, various studies are currently in progress to reduce the volume of the stacked semiconductor package.

### BRIEF SUMMARY OF THE INVENTION

Embodiments of the present invention are directed to a stacked semiconductor package, which is reduced in volume to allow for a more compact size.

In one embodiment, a stacked semiconductor package may comprise a substrate having a connection pad; a first semiconductor chip having upper and lower faces and first and second sides, a plurality of first bonding pads disposed near an edge of the first semiconductor chip, and a plurality of redistributions extending from the first bonding pads to a middle of the upper face; a wire for electrically connecting the first bonding pad and the connection pad; and a second semiconductor chip disposed over the first semiconductor chip but leaving the first bonding pads exposed, and a plurality of second bonding pads disposed in the lower surface of the second semiconductor chip and connected to the redistribution in a flip-chip manner.

The connection pad formed on the substrate may be disposed in the area outside of the first semiconductor chip.

The stacked semiconductor package described above may further include a first adhesive member interposed between the substrate and the first semiconductor chip; and a second adhesive member interposed between the first semiconductor chip and the second semiconductor chip with an opening for exposing the second bonding pad.

The first and second adhesive members may be either an adhesive agent or an adhesive film.

The first semiconductor chip has a chip select redistribution on the upper face of the semiconductor chip, wherein a select signal can be applied to select one of the semiconductor chips.

The first semiconductor chip and the second semiconductor chip may be the same size, such that the first and second semiconductor chips overlap.

A connection member for electrically connecting the second bonding pad and the redistribution may be interposed between the second bonding pad and the redistribution.

The connection member may be a solder.

The stacked semiconductor package may further comprise a molding member for covering the first and second semiconductor chips and the wire.

Instead of the semiconductor chips being the same size, the first semiconductor chip and the second semiconductor chip may be different sizes.

When the semiconductor chips are different sizes, the edges of the semiconductor chips (where the bonding pads are not located) may be formed parallel too each other (i.e. the edges opposite the bonding pads no longer overlap).

### BRIEF DESCRIPTION OF THE DRAWINGS

FIG. 1 is a partially broken perspective view illustrating a stacked semiconductor package in accordance with a first embodiment of the present invention.

FIG. 2 is a sectional view taken along a line I-I′ of FIG. 1.

FIG. 3 is a plan view illustrating the substrate shown in FIG. 1.

FIG. 4 is a plan view illustrating the first semiconductor chip shown in FIG. 1.

FIG. 5 is a plan view illustrating the second semiconductor chip shown in FIG. 1.

FIG. 6 is an enlarged view of part ‘A’ in FIG. 2.

FIG. 7 is a sectional view illustrating a stacked semiconductor package in accordance with a second embodiment of the present invention.

### DESCRIPTION OF SPECIFIC EMBODIMENTS

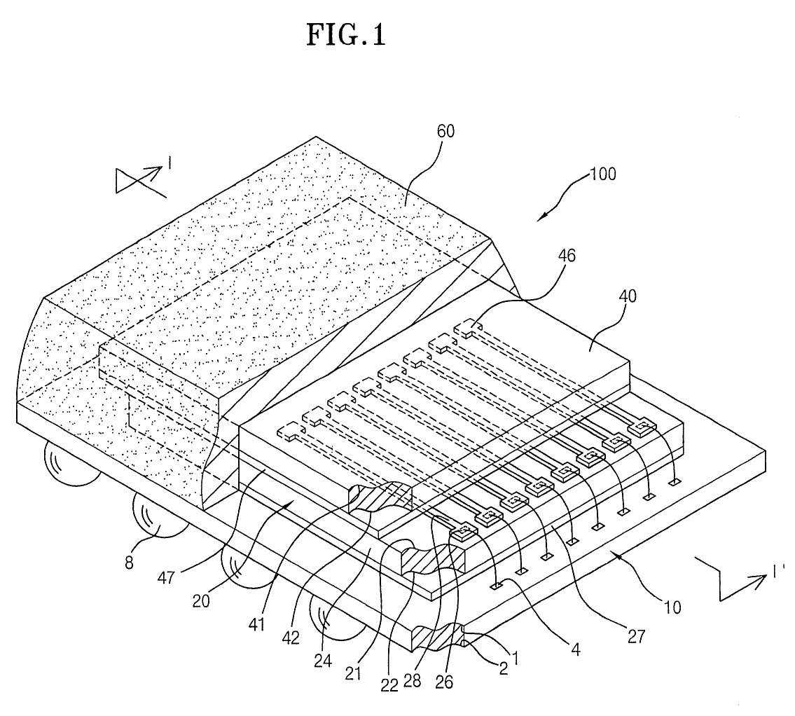

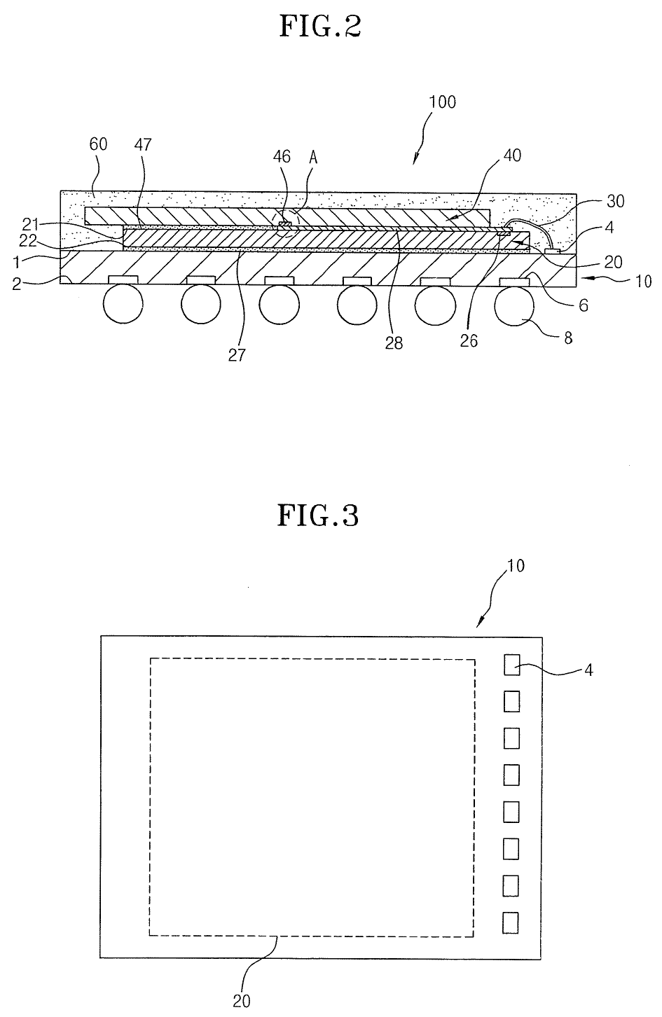

FIG. 1 is a partially broken perspective view illustrating a stacked semiconductor package in accordance with a first embodiment of the present invention. FIG. 2 is a sectional view taken along a line I-I′ of FIG. 1.

Referring to FIGS. 1 and 2, a stacked semiconductor package 100 includes a substrate 10, a first semiconductor chip 20, a wire 30 and a second semiconductor chip 40. In addition, the stacked semiconductor package 100 may further include a molding member 60.

FIG. 3 is a plan view illustrating the substrate shown in FIG. 1.

Referring to FIGS. 1 through 3, the substrate 10 has, for example, the shape of a rectangular plate. In the present embodiment, the substrate 10 may be, for example, a printed circuit board. The substrate 10 (having the shape of a rectangular plate) has a first face 1 and a second face 2 that opposes the first face 1.

The substrate 10 includes a connection pad 4, a ball land 6 and a solder ball 8.

The connection pad 4 is disposed on the first face 1 of the substrate 10. For example, the connection pad 4 is disposed at an outer are of the the substrate 10. The Dotted line in FIG. 3 indicates an area for disposition of the first semiconductor chip 20.

The ball land 6 is disposed over the second face 2 of the substrate 10 and is electrically connected to the connection pad 4. The solder ball 8 is electrically connected to the ball land 6.

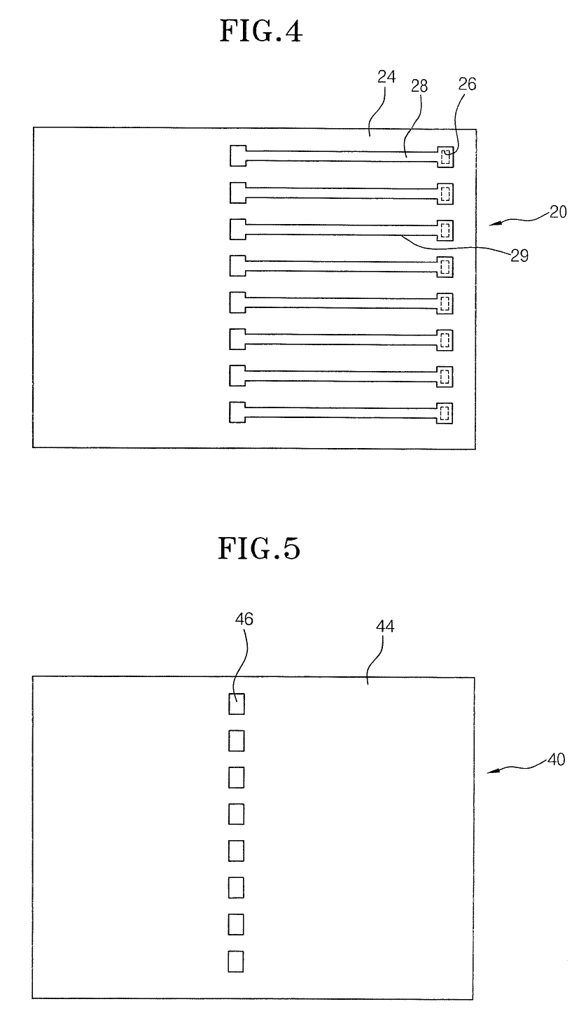

FIG. 4 is a plan view illustrating the first semiconductor chip shown in FIG. 1.

Referring to FIGS. 1 and 4, the first semiconductor chip 20 is disposed, for example, over the first face 1 of the substrate 10 at a predetermined distance from the connection pad 4.

The first semiconductor chip 20 includes a first semiconductor chip body 24, a first bonding pad 26, a redistribution 28 and a chip select redistribution 29.

The first semiconductor chip body 24 has, for example, a rectangular parallelepiped shape. The first semiconductor chip body 24 with the rectangular parallelepiped shape has a first size. The first semiconductor chip body 24 having the first size has an upper face 21 and a lower face 22 that opposes the upper face 21.

The lower face 22 of the first semiconductor chip body 24 faces the first face 1 of the substrate 10. The lower face 22 of the first semiconductor chip body 24 may be attached to the first face 1 of the substrate 10 by a first adhesive member 27. The first adhesive member 27 may include, for example, an adhesive agent, an adhesive tape such as double-sided adhesive tape, an adhesive film, etc.

The first bonding pad 26 is disposed over the upper face 21 of the first semiconductor chip body 24. A plurality of the first bonding pads 26 is disposed, for example, along an edge of the first semiconductor chip body 24.

A plurality of redistributions 28 is disposed over the upper face 21 of the first semiconductor chip body 24. The redistributions 28 correspond to respective first bonding pads 26.

The redistribution 28 has a linear shape when viewed from above. One end of the redistribution 28 having the linear shape is electrically connected to the first bonding pad 26 and the opposite end extends toward the middle part of the upper face 21 of the first semiconductor chip body 24.

A seed metal pattern (not shown) may be disposed between the redistribution 28 and the upper face 21 of the first semiconductor chip lo body 24. The seed metal pattern may be formed selectively between the redistribution 28 and the upper face 21 of the first semiconductor chip body 24 in order to form the redistribution 28 in a plating manner.

The chip select redistribution 29 is disposed over the upper face 21 of the first semiconductor chip body 24 with the other redistributions 28. One end of the chip select redistribution 29 is electrically connected to one of the first bonding pads 26 and the other end extends toward a middle part of the upper face 21. A chip select signal is applied to the chip select redistribution 29 for selecting one of the semiconductor chips.

Referring again to FIGS. 1 and 2, the wire 30 electrically connects the connection pad 4 and the first bonding pad 26 of the first semiconductor chip 26.

FIG. 5 is a plan view illustrating the second semiconductor chip shown in FIG. 1.

Referring to FIGS. 1, 2, and 5, the second semiconductor chip 40 includes a second semiconductor chip body 44 and a plurality of second bonding pads 46.

The second semiconductor chip body 44 has, for example, a rectangular parallelepiped shape. The second semiconductor chip body 44 with a rectangular parallelepiped shape has a size (called second size for the purpose of distinction) that is substantially the same as that of the first semiconductor chip body 24. The second semiconductor chip body 44 having the second size has an upper face 41 and a lower face 42 that opposes the upper face 41.

The lower face 42 of the second semiconductor chip body 44 faces the upper face 21 of the first semiconductor chip body 24, and the lower face 42 of the second semiconductor chip body 44 may be attached to the upper face 21 of the first semiconductor chip body 24 by a second adhesive member 47. The second adhesive member 47 has openings for exposing each of the second bonding pads 46 of the second semiconductor chip body 44. The second adhesive member 47 may include, for example, an adhesive agent or an adhesive tape such as a double-sided adhesive tape.

The second bonding pads 46 are disposed at the middle of the bottom face 42 of the second semiconductor chip body 44. The second bonding pads 46 are disposed at positions corresponding to respective redistributions 28 which are connected electrically with the first bonding pad 26 of the first semiconductor chip body 24 respectively.

The second semiconductor chip 46 having the second bonding pads 46 is electrically connected to the redistribution 28 disposed over the first semiconductor chip body 24 in a flip-chip manner.

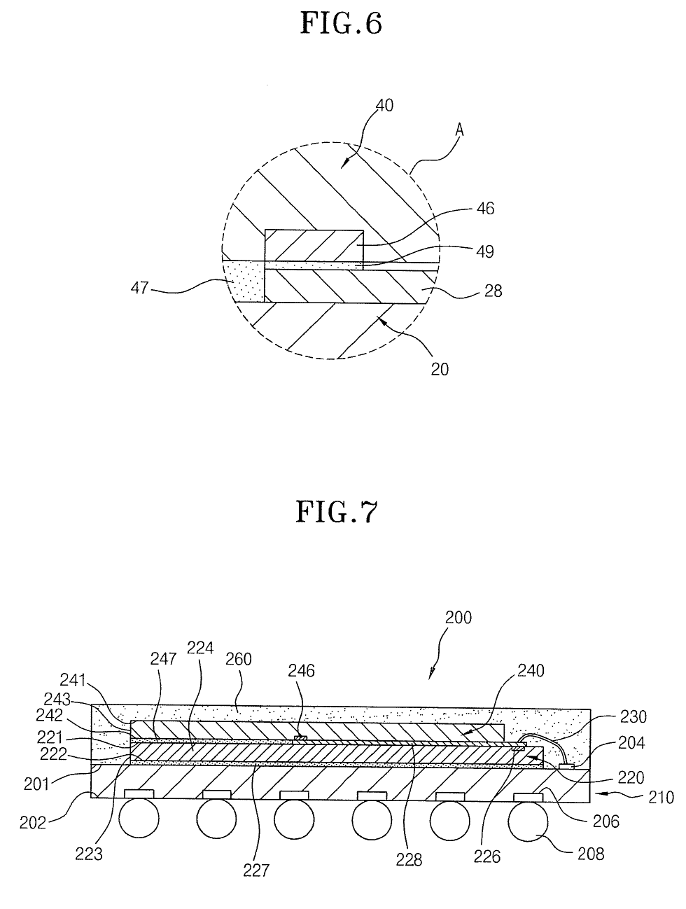

FIG. 6 is an enlarged view of part ‘A’ in FIG. 2.

Referring to FIG. 6, in order to electrically connect the second bonding pad 46 and the redistribution 28 at a low temperature, a connection member 49 is disposed between the second bonding pad 46 and the redistribution 28. The connection member 49 may be, for example, a solder containing lead.

The connection member 49 may be disposed, for example, on the second bonding pad 46. Alternatively, the connection member 49 may be disposed on the redistribution 28 corresponding to the second bonding pad 46.

Referring again to FIG. 1, the molding member 60 covers the substrate 10, the first semiconductor chip 20, the wire 30 and the second semiconductor chip 40. Examples of material that may be used as the molding member 60 include epoxy resin, etc.

Although the stacked semiconductor package 100 described above has first and second semiconductor chips 20 and 40 disposed over the substrate 10, the stacked semiconductor package 100 may have three or more disposed over the substrate 10.

FIG. 7 is a sectional view illustrating a stacked semiconductor package in accordance with a second embodiment of the present invention.

Referring to FIG. 7, a stacked semiconductor package 200 includes a substrate 210, a first semiconductor chip 220, a wire 230 and a second semiconductor chip 240. In addition, the stacked semiconductor package 200 may further include a molding member 260.

The substrate 210 may have the shape of a rectangular plate, and it may be a printed circuit board. The substrate 210 has a first face 201 and a second face 202 that opposes the first face 201.

The substrate 210 includes a connection pad 204, a ball land 206 and a solder ball 208.

The connection pad 204 is disposed over the first face 201 of the substrate 210 and disposed at an outer area of the substrate 210.

The ball land 206 disposed in the second face 202 of the substrate 210 is electrically connected to the connection pad 204. The ball land 206 is electrically connected to the solder ball 208.

The first semiconductor chip 220 disposed over the first face 201 of the substrate 210 is disposed at a predetermined distance from the connection pad 204.

The first semiconductor chip 220 includes a first semiconductor chip body 224, a first bonding pad 226, a redistribution 228, and a chip select redistribution (not shown).

The first semiconductor chip body 224 may have a rectangular parallelepiped shape, and the first semiconductor chip body 224 has an upper face 221 and a lower face 222 that opposes the upper face 221.

The lower face 222 of the first semiconductor chip body 224 faces the first face 201 of the substrate 210. The first face 201 and the substrate 210 are attached to each other using a first adhesive member 227. The first adhesive member 227 may include, for example, an adhesive agent or an adhesive tape such as a double-sided adhesive tape.

First bonding pads 226 are disposed in the upper face 221 of the first semiconductor chip body 224. The first bonding pads 226 are disposed along an edge over the upper face 221 of the first semiconductor chip body 224.

The redistribution 228 disposed over the upper face 221 of the first semiconductor chip body 224 is electrically connected to the first bonding pad 26.

The redistribution 228 has a bar shape when viewed from above. One end of the redistribution 228 is electrically connected with the first bonding pad 226 and the opposite end extends toward the middle part of the upper face 221 of the first semiconductor chip body 224.

A seed metal pattern (not shown) may be disposed between the redistribution 228 and the upper face 221 of the first semiconductor chip body 224. The seed metal pattern may be selectively formed between the redistribution 228 and the upper face 221 of the first semiconductor chip body 224 in order to form the redistribution 228 in a plating manner.

The chip select redistribution 229 is disposed over the upper face 221 of the first semiconductor chip body 224 along with the redistribution 228. One end of the chip select redistribution 229 is electrically connected to one of the first bonding pads 226 and the opposite end extends toward a middle part of the upper face 221. A chip select sign is applied to the chip select redistribution 229 for selecting one of the the semiconductor chips.

The wire 230 electrically connects the connection pad 204 and the first bonding pad 226 of the first semiconductor chip 226.

The second semiconductor chip 240 includes a second semiconductor chip body 244 and a second bonding pad 246.

The second semiconductor chip body 244 having a rectangular parallelepiped shape has a size (referred to as a second size in order to differentiate) that is different from the size of the first semiconductor chip body 224. The second size of the second semiconductor chip body 244 is smaller than the size of the first semiconductor chip body 224. For example, widths of the first and second semiconductor chip bodies 224 and 244 are substantially the same, but the length of the second semiconductor chip body 244 is shorter than the length of the first semiconductor chip body 224.

In the present embodiment, a side surface 243 disposed along a longitudinal direction of the second semiconductor chip body 244 and a side surface 223 disposed along a longitudinal direction of the first semiconductor chip body 224 are aligned with each other. As such, it is possible to reduce the planar area of the stacked semiconductor package 200 by aligning these side surfaces 243 and 223 of the second semiconductor chip body 244 and the first semiconductor chip body 224.

The second semiconductor chip body 244 has an upper face 241 and a lower face 242 that opposes the upper face 241.

The lower face 242 of the second semiconductor chip body 244 faces the upper face 221 of the first semiconductor chip body 224. The lower face 242 of the first semiconductor chip body 244 can be attached to the upper face 221 of the first semiconductor chip body 224 lo by a second adhesive member 247. The second adhesive member 247 may include, for example, an adhesive agent or an adhesive tape such as a double-sided adhesive tape.

The second bonding pad 246 is disposed at the middle of the lower face 242 of the second semiconductor chip body 244. The second bonding pads 246 are disposed at positions corresponding to the respective redistributions 228 that are electrically connected to the first bonding pad 226 of the first semiconductor chip body 224.

The second semiconductor chip 246 having the second bonding pads 246 is electrically connected to the redistribution 228 disposed over the first semiconductor chip body 224 in a flip-chip manner. In the present embodiment, it is possible to reduce the thickness of the stacked semiconductor package 200 by connecting the second semiconductor chip 240 with the redistribution 228 of the first semiconductor chip 224 in the flip-chip manner.

In order to electrically connect the second bonding pad 246 and the redistribution 228 at a low temperature, a connection member (not shown) is disposed between the second bonding pad 246 and the redistribution 228. The connection member may be, for example, a solder containing lead.

The connection member may be disposed on the second bonding pad 246. Alternatively, the connection member may be disposed on the redistribution 228 corresponding to the second bonding pad 246.

The molding member 260 covers the substrate 210, the first semiconductor chip 220, the wire 230, and the second semiconductor chip 240. Examples of material that may be used as the molding member 60 include epoxy resin, etc.

As is apparent from the above description, it is possible to significantly reduce the planar area and thickness of a stacked semiconductor package by wire bonding a substrate to the bonding pads of the lower semiconductor chip in the stacked semiconductor package and electrically connecting the bonding pad of the upper semiconductor chip to a redistribution that extends from the bonding pad of the lower semiconductor chip to the bonding pad of the upper semiconductor chip.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A stacked semiconductor package comprising:
a substrate having a plurality of connection pads;
a first semiconductor chip disposed over the substrate, the first semiconductor chip having an upper face, a lower face, a first side, and a second side,
a plurality of first bonding pads disposed in the upper face of the first semiconductor chip, the first bonding pads being located at the edge of the semiconductor chip corresponding to the first side,
a plurality of redistributions connected to the first bonding pads and extending from the first bonding pad to a middle of the upper face;
a wire for electrically connecting the first bonding pads to the corresponding connection pads;
a second semiconductor chip having a top face, a bottom face, a first side surface, and a second side surface, the second semiconductor chip being disposed over the first semiconductor chip such that an area of the first semiconductor chip corresponding to the first bonding pads is exposed, and
a plurality of second bonding pads disposed in the bottom face of the second semiconductor chip, the second bonding pads being connected to the corresponding redistributions.

2. The stacked semiconductor package according to claim 1, wherein the connection pads are disposed on a top portion of the substrate that is outside of the first semiconductor chip.

3. The stacked semiconductor package according to claim 1, further comprising:
a first adhesive member interposed between the substrate and the first semiconductor chip; and
a second adhesive member interposed between the first semiconductor chip and the second semiconductor chip, the second adhesive member and having a plurality of openings for exposing the second bonding pads.

4. The stacked semiconductor package according to claim 3, wherein the first and second adhesive members are an adhesive agent or an adhesive film.

5. The stacked semiconductor package according to claim 1, further comprising:
a chip select redistribution disposed on the upper face of the first semiconductor chip, wherein a select signal can be applied for selecting one of the semiconductor chips.

6. The stacked semiconductor package according to claim 1, wherein the first semiconductor chip and the second semiconductor chip are the same size, such that the first and second semiconductor chips overlap.

7. The stacked semiconductor package according to claim 1, wherein a connection member is interposed between the second bonding pad and the redistribution to electrically connect the connection member to the bonding pad.

8. The stacked semiconductor package according to claim 7, wherein the connection member includes a solder.

9. The stacked semiconductor package according to claim 1, further comprising:
a molding member for covering the first and second semiconductor chips, the substrate, and the wire.

10. The stacked semiconductor package according to claim 1, wherein the first semiconductor chip and the second semiconductor chip are different sizes.

11. The stacked semiconductor package according to claim 10, wherein the second side surface of the second semiconductor chip is coplanar to the second side of the first semiconductor chip, such that the second side surface of the second semiconductor chip does not extend beyond the second side of the first semiconductor chip.
